(19) United States
(12) Patent Application Publication
(10) Pub. No.: US 2024/0242919 A1
(43) Pub. Date: Jul. 18, 2024

(54) MULTI CHARGED PARTICLE BEAM WRITING APPARATUS

(71) Applicant: NuFlare Technology, Inc., Yokohama-shi (JP)

(72) Inventor: Hirofumi MORITA, Yokohama-shi (JP)

(73) Assignee: NuFlare Technology, Inc., Yokohama-shi (JP)

(21) Appl. No.: 18/474,329

(22) Filed: Sep. 26, 2023

Related U.S. Application Data
(63) Continuation of application No. PCT/JP2023/000961, filed on Jan. 16, 2023.

(51) Int. Cl. H01J 37/141; G03F 7/00; G03F 7/20; H01J 37/04; H01J 37/145; H01J 37/317

(52) U.S. Cl. CPC H01J 37/141; G03F 7/2059; G03F 7/70191; H01J 37/045; H01J 37/145; H01J 37/3177

(57) ABSTRACT

In one embodiment, a multi charged particle beam writing apparatus includes two or more-stage objective lenses each comprised of a magnetic lens, and configured to focus a multi charged particle beam on a substrate, which has passed through a limiting aperture member, and three or more correction lenses correcting an imaging state of the multi charged particle beam on the substrate. The three or more correction lenses are comprised of a first magnetic correction lens, and two or more correction lenses, the two or more correction lenses are placed inside a lens magnetic field of one of the two or more-stage objective lenses, and one or no electrostatic correction lens is placed inside a magnetic field of each of the two or more-stage objective lenses.

### TECHNICAL FIELD

The present invention relates to a multi charged particle beam writing apparatus.

### BACKGROUND ART

As LSI circuits are increasing in density, the line width of circuits of semiconductor devices is becoming finer. To form a desired circuit pattern onto a semiconductor device, a method of reducing and transferring, by using a reduction-projection exposure apparatus, onto a wafer a highly precise original image pattern formed on a quartz is employed. A so-called electron beam lithography technique, in which a pattern is formed by exposing a resist using an electron beam writing apparatus, is used to produce a highly precise original image pattern.

As an electron beam writing apparatus, a writing apparatus using a multi-beam is under active development, which substitutes for a conventional single beam writing apparatus that deflects a single beam and radiates the beam to a desired position on a sample. Use of a multi-beam allows many beams to be radiated as compared to when writing is performed with a single electron beam, thus the throughput can be significantly improved. In a writing apparatus using a multi-beam method, for example, an electron beam emitted from an electron source is passed through a shaping aperture array member having a plurality of openings to form a multi-beam, blanking control is performed on beams by a blanking aperture array substrate, and unblocked beams are reduced by an optical system, and radiated to a sample placed on a movable stage.

In the electron beam writing apparatus, beams in each shot are focused on a sample by an objective lens, dynamic focus correction (dynamic focus) is performed during writing using, for example, an electrostatic lens so as to correspond to the irregularities of the sample surface, and the position (imaging height) in the optical axis direction of the multi-beam array image is corrected. Here, the optical axis refers to the central axis of an optical system in the course from emission of an electron beam to irradiation of the sample. However, when dynamic focus is performed, rotation and magnification change occur in the beam array image on the sample, and the writing positional accuracy deteriorates. Thus, the rotation and magnification change of the beam array image due to the dynamic focus is required to be reduced as much as possible.

In order to reduce the rotation and magnification change of the beam array image due to the dynamic focus, a multi beam writing apparatus has been proposed, in which three electrostatic lenses are provided, and at least one electrostatic lens is placed in the lens magnetic field of each of two-stage objective lenses (see, for example, PTL 1).

In an electron optical system of the multi beam writing apparatus, to increase the accuracy of a beam array image dimensions and array pitch, the beam array image needs to be formed on the sample surface with a high reduction ratio, for example, a magnification of approximately 1/200. In order to achieve such a high reduction ratio as well as to secure an interval (called a working distance in many cases) between the lower surface of a lens and a sample to allow a sample to move, the number of times of imaging the beam array image by an objective lens needs to be at least twice.

When the number of times of imaging is set to two, the number of stages of the objective lenses is two. Here, the “stage” means that a single imaging (image formation) is performed, and one-stage objective lens is comprised of a single lens in many cases; however, in order to reduce aberration and distortion, one-stage objective lens may be comprised of two or more magnetic lenses in proximity (in other words, a single imaging may be performed by two or more magnetic lenses in proximity).

In PTL 1, three electrostatic lenses are placed inside the magnetic field of two-stage objective lenses, therefore, two electrostatic lenses are placed in proximity inside the magnetic field of one of the two-stage objective lenses. A region where a lens magnetic field is present is a limited short region including a position where a magnetic pole is present and an area around the position in the beam travel direction. Most of the region where a lens magnetic field is present is the region surrounded by magnetic poles with a small diameter, thus is the space that is limited narrowly in a direction perpendicular to the beam travel direction.

On the other hand, the electrostatic lenses need to be placed in a vacuum where an electron beam passes through, thus a complicated structure, such as a vacuum seal, a wire lead-out from a vacuum area, is necessary. Furthermore, to apply a voltage to the electrostatic lenses, an insulator that supports the lens electrodes is required, and to prevent beam position variation due to charging, a structure is also needed that surrounds the insulator sufficiently with a conductor so as not to be seen from the electron beam trajectory. It is difficult to construct two sets of these complicated structures in a short region in which a lens magnetic field is present and in a narrow space surrounded by magnetic poles.

In an electron beam writing apparatus, when a sample is irradiated with an electron beam, due to an effect of the electrons (reflected electrons) that have collided with the sample and reflected, and the electrons (secondary electrons) generated by the electrons incident on the sample, drift (in other words, beam position variation, beam position instability) may occur, and a position deviated from a target position may be irradiated. Thus, the electrostatic lenses are operated in a positive voltage range with respect to the sample surface, and the secondary electrons are accelerated and guided upward from the sample surface (see, for example, PTL 2).

When two electrostatic lenses are placed inside an objective lens magnetic field and operated with a positive voltage with respect to the sample surface, if the voltage of the upstream electrostatic lens becomes lower than the voltage of the downstream electrostatic lens, the secondary electrons from the sample surface stay in the vicinity of the boundary between the two electrostatic lenses, and beams (primary beams) are deflected by the Coulomb force from the staying secondary electrons, thus the beam position becomes unstable, which causes drift.

Because the voltage applied to the electrostatic lens changes in response to the sample surface height during writing, the magnitude relationship between the voltages of the two electrostatic lenses may be reversed during writing, and drift, which has not occurred at the start of writing, may occur in the middle of writing.

Like this, a problem arises in that when two electrostatic lenses are placed in proximity inside the magnetic field of one-stage objective lens, drift occurs due to stay of secondary electrons.

PTL 1: JP 2013-197289 A

PTL 2: JP 2013-191841 A

### SUMMARY OF INVENTION

It is an object of the present invention to provide a multi charged particle beam writing apparatus that can secure space for placing a focus correction lens as well as prevent secondary electrons from staying, and stabilize the beam irradiation position.

According to one aspect of the present invention, a multi charged particle beam writing apparatus includes a plurality of blankers performing blanking deflection on each of beams in a multi charged particle beam, a limiting aperture member blocking a beam in the multi charged particle beam, the beam being deflected by the blanker to achieve a beam-OFF state, two or more-stage objective lenses each comprised of a magnetic lens, and configured to focus the multi charged particle beam on a substrate, which has passed through the limiting aperture member, and three or more correction lenses correcting an imaging state of the multi charged particle beam on the substrate, wherein the three or more correction lenses are comprised of a first magnetic correction lens, and two or more correction lenses, the two or more correction lenses are placed inside a lens magnetic field of one of the two or more-stage objective lenses, and one or no electrostatic correction lens is placed inside a magnetic field of each of the two or more-stage objective lenses.

### Advantageous Effects of Invention

According to the present invention, it is possible to secure space for placing a focus correction lens as well as prevent the secondary electrons from staying, and stabilize the beam irradiation position.

### BRIEF DESCRIPTION OF DRAWINGS

FIG. 1 is a schematic diagram of a multi charged particle beam writing apparatus according to a first embodiment of the present invention.

FIG. 2 is a schematic diagram of a shaping aperture array substrate.

FIG. 3 is a schematic diagram of a multi charged particle beam writing apparatus according to a second embodiment of the present invention.

FIG. 4 is a schematic diagram of a multi charged particle beam writing apparatus according to a third embodiment of the present invention.

FIG. 5 is a schematic diagram of a multi charged particle beam writing apparatus according to a modification.

FIG. 6 is a schematic diagram of a multi charged particle beam writing apparatus according to a fourth embodiment of the present invention.

FIG. 7 is a schematic diagram of a multi charged particle beam writing apparatus according to a modification.

FIG. 8 is a schematic diagram of a multi charged particle beam writing apparatus according to a modification.

### DESCRIPTION OF EMBODIMENTS

Hereinafter, an embodiment of the present invention will be described based on the drawings.

### First Embodiment

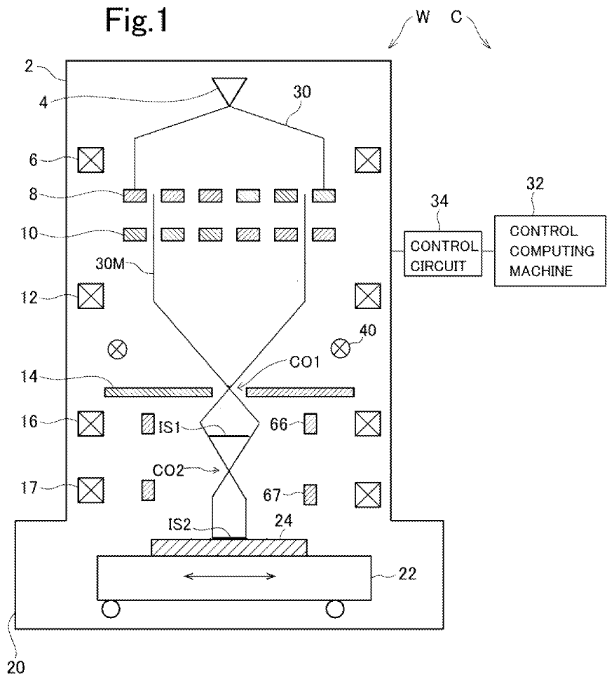

FIG. 1 is a schematic diagram of a multi charged particle beam writing apparatus according to a first embodiment of the present invention. In this embodiment, a configuration will be described in which an electron beam is used as an example of a charged particle beam. However, the charged particle beam is not limited to an electron beam, and may be another charged particle beam such as an ion beam.

The writing apparatus includes a writer W that radiates an electron beam to a substrate 24 as a writing target to write a desired pattern, and a controller C that controls the operation of the writer W.

The writer W has an electron optical column 2 and a writing chamber 20. In the electron optical column 2, an electron source 4, an illumination lens 6, a shaping aperture array substrate 8, a blanking aperture array substrate 10, a reduction lens 12, a magnetic correction lens 40, a limiting aperture member 14, two-stage objective lenses 16, 17, and two electrostatic correction lenses 66, 67 are provided.

The illumination lens 6 is placed between the electron source 4 and the shaping aperture array substrate 8. The illumination lens 6 may be a magnetic lens or may be an electrostatic lens. The reduction lens 12 is placed between the blanking aperture array substrate 10 and the objective lens 16. The reduction lens 12 may be a magnetic lens or may be an electrostatic lens. The objective lenses 16, 17 are magnetic lenses.

The magnetic correction lens 40 is placed between the reduction lens 12 and the objective lens 16. In addition, the magnetic correction lens 40 is placed outside the lens magnetic fields of the objective lenses 16, 17. When the reduction lens 12 is a magnetic lens, the magnetic correction lens 40 is placed outside the magnetic field of the magnetic lens. The magnetic field (on-axis magnetic flux density) of a magnetic lens attenuates as the distance from the lens magnetic poles increases. The on-axis magnetic flux density attains a maximum normally on the optical axis near the middle between a pair of magnetic poles (two magnetic poles) of the magnetic lens. Empirically, the region where the on-axis magnetic flux density is higher than e.g., 1/10 its maximum value, or the region where the magnetic flux density is higher than its local minimum can be regarded as “inside the magnetic field”, and the region other than those regions can be regarded as “outside the magnetic field”.

In order to reduce aberration and distortion, one-stage objective lens may be comprised of two or more magnetic lenses in proximity, and in such a situation, even when a region with the magnetic flux density lower than or equal to 1/10 or reaching a local minimum occurs between the magnetic lenses in proximity constituting one-stage objective lens, the region is not regarded as the boundary between inside and outside of the lens magnetic field of the objective lens, but is regarded as “within magnetic field”.

The magnetic correction lens 40 generates a minute rotationally symmetric magnetic field to correct the imaging state. For example, the magnetic correction lens 40 is a circular coil or a solenoid coil having the beam optical axis as a central axis, and a current for correction is passed therethrough. The coil may be surrounded by a magnetic material such as ferrite.

Although the limiting aperture member 14 is disposed between the reduction lens 12 and the objective lens 16, a configuration may be adopted in which the limiting aperture member 14 is disposed between the objective lens 16 and the objective lens 17. The objective lens 17 is placed most downstream in the beam travel direction among the plurality of objective lenses provided in the writing apparatus. The objective lens 16 is placed upstream of the objective lens 17 in the beam travel direction. Because of such a positional relationship, the objective lens 16 may be called an upper-stage objective lens, and the objective lens 17 may be called a lower-stage objective lens. In addition, the objective lens 17 may be called a final-stage objective lens. The electrostatic correction lens 66 is placed within the lens magnetic field (i.e., inside the magnetic field) of the objective lens 16 comprised of a magnetic lens. The electrostatic correction lens 67 is placed within the lens magnetic field of the objective lens 17 comprised of a magnetic lens.

The electrostatic correction lenses 66 and 67 generate a minute rotationally symmetric electrostatic field to correct the imaging state of the multi-beam. For example, each of the electrostatic correction lenses 66 and 67 is comprised of a cylindrical electrode, to which a voltage for correction is applied. A cylindrical earth electrode may be placed above and below the electrode, to which a voltage is applied.

Note that a configuration may be adopted in which a cylindrical or ring-shaped electrode is divided (for example, an electrode is divided as in 8-pole deflector), and voltages for generating an electrostatic focusing field (rotationally symmetric electrostatic field), an electrostatic deflection field, and an electrostatic multipole field are added and applied to a group of these electrodes so that the group serves as a lens, a deflector, and a multipole. Since the configuration also generates an electrostatic field having a lens effect, such a group of electrodes is also included in one electrostatic correction lens.

XY stage 22 is disposed in the writing chamber 20. The substrate 24 as a writing target is placed on the XY stage 22. The substrate 24 as a writing target is, for example, a mask blank or a semiconductor substrate (silicon wafer).

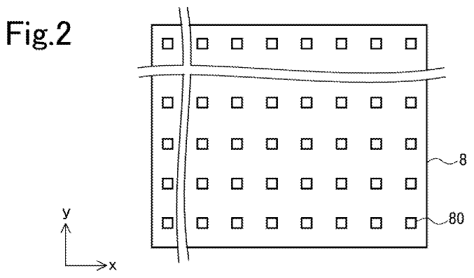

An electron beam 30 emitted from the electron source 4 illuminates the shaping aperture array substrate 8 substantially perpendicularly by the illumination lens 6. FIG. 2 is a conceptual diagram illustrating the configuration of the shaping aperture array substrate 8. In the shaping aperture array substrate 8, openings 80 in vertical (y direction) m rows×horizontal (x direction) n rows (m, n≥2) are formed in a matrix pattern with a predetermined arrangement pitch. For example, the openings 80 with 512 rows×512 rows are formed. The openings 80 are all formed in rectangular shapes having the same dimension. The openings 80 may be circular with the same diameter.

The electron beam 30 illuminates a region including all openings 80 of the shaping aperture array substrate 8. Part of the electron beam 30 passes through these multiple openings 80, thereby forming a multi-beam 30M as illustrated in FIG. 1.

In the blanking aperture array substrate 10, through-holes are formed corresponding to the arrangement positions of the openings 80 of the shaping aperture array substrate 8, and a blanker consisting of two electrodes as a pair is disposed in each through-hole. The multi-beam 30M passing through the through-holes are each independently deflected by a voltage applied to a corresponding blanker. Blanking control is performed on each beam by the deflection. In this manner, blanking deflection is performed by the blanking aperture array substrate 10 on each beam in the multi-beam 30M which has passed through the plurality of openings 80 of the shaping aperture array substrate 8.

Each beam size and arrangement pitch of the multi-beam 30M which has passed through the blanking aperture array substrate 10 is reduced by the reduction lens 12. The multi-beam 30M travels such that a crossover CO1 is formed slightly upstream of the objective lens 16. The limiting aperture member 14 is disposed so that the center of the opening formed in the limiting aperture member 14 substantially matches the crossover CO1. An electron beam deflected by a blanker of the blanking aperture array substrate 10 undergoes displacement in trajectory, deviates from the opening of the limiting aperture member 14, and is blocked by the limiting aperture member 14. In contrast, an electron beam not deflected by a blanker of the blanking aperture array substrate 10 passes through the opening of the limiting aperture member 14.

In this manner, the limiting aperture member 14 blocks those electron beams deflected by blankers of the blanking aperture array substrate 10 to achieve a beam-OFF state. The beam which has passed through the limiting aperture member 14 from beam ON to beam OFF provides the electron beam for a single shot.

The multi-beam 30M which has passed through the limiting aperture member 14 is affected by the upper-stage objective lens 16 to form a reduced intermediate image IS1 of the plurality of openings 80 of the shaping aperture array substrate 8, and to form a crossover CO2. The lower-stage objective lens 17 reduces the intermediate image IS1, and forms an image (beam array image) IS2 of the plurality of openings 80 of the shaping aperture array substrate 8 on the surface of the substrate 24, the image having a desired reduction ratio. Note that the reduction ratio is a reciprocal of magnification, and refers to the ratio of the size (or pitch) of the image formed on the surface of the substrate 24 to the size (or pitch) of the electron beam which is formed by part of the electron beam 30 passing through the plurality of openings 80 of the shaping aperture array substrate 8, for example.

Use of the objective lenses in two stages can achieve a high reduction ratio (for example, a magnification of approximately 1/200) as well as secure the interval (working distance) by which the substrate 24 is movable between the lower surface of the final-stage lens (the objective lens 17) and the substrate 24.

The electrostatic correction lenses 66, 67 are operated in a positive voltage range with respect to the surface of the substrate 24. For example, as in the case where the ratio of the area of a pattern to be written to the entire writing area is extremely low, when the yield of reflected electrons and secondary electrons in the sample is few, and it can be determined that their effect may not be taken into consideration, the electrostatic correction lenses 66, 67 may be operated in a negative voltage range.

The electron beams (the entire multi-beam) which have passed through the limiting aperture member 14 are collectively deflected by a deflector (not illustrated) in the same direction, and are radiated to the substrate 24. The deflector (not illustrated) may be disposed downstream of the blanking aperture array substrate 10, and disposing the deflector downstream of the upper-stage objective lens 16 is advantageous in reducing distortion and aberration. When the XY stage 22 moves continuously, the beams are deflected so that the beam irradiation position follows the movement of the XY stage 22. Also, the writing position changes every moment due to movement of the XY stage 22, and the surface height of the substrate 24 irradiated with the multi-beam changes. To cope with this, defocus of the multi-beam is dynamically corrected (dynamic focus) during writing by the magnetic correction lens 40, and the electrostatic correction lenses 66, 67.

The multi-beam radiated at a time is ideally arranged with a pitch which is obtained by dividing (in other words, multiplying by a magnification) the arrangement pitch of the plurality of openings 80 of the shaping aperture array substrate 8 by the above-mentioned desired reduction ratio. The writing apparatus performs a raster-scan writing operation of continuously radiating a shot beam sequentially, and when a desired pattern is written, needed beams are controlled at beam-ON by blanking control according to a pattern.

The controller C has a control computing machine 32 and a control circuit 34. The control computing machine 32 performs data conversion processes in multiple stages on writing data to generate shot data specific to the apparatus, and outputs the shot data to the control circuit 34. In the shot data, the irradiation amounts and irradiation position coordinates of shots are defined. The control circuit 34 determines an irradiation time by dividing the irradiation amount of each shot by a current density, and applies a deflection voltage to a corresponding blanker of the blanking aperture array substrate 10 so that when a relevant shot is performed, beam-ON is achieved only for the calculated irradiation time.

The control computing machine 32 holds data of the later-described relational expression for coordination of the amounts of excitation of the magnetic correction lens 40, and the electrostatic correction lenses 66, 67, and calculates the amount of excitation of each correction lens using the relational expression. The control circuit 34 provides the amounts of excitation calculated from the relational expression to the magnetic correction lens 40, and the electrostatic correction lenses 66, 67 to cause the lenses to be operated. Note that the amounts of excitation refer to an excitation current for a magnetic correction lens, and refer to an applied voltage for an electrostatic correction lens.

The magnetic correction lens has an effect (rotational effect) of rotating a beam image, and the effect occurs regardless of whether the position of the magnetic correction lens in the optical axis direction is inside or outside the magnetic field of the objective lens. Rotation of an image is simple sum of the rotational effect of the objective lens magnetic field, and the rotational effect of the magnetic correction lens magnetic field, and even when both magnetic fields overlap, no synergetic effect (rotational effect proportional to the product of both magnetic fields) occurs. In this embodiment, when the reduction lens 12 is a magnetic lens, the rotation effect of the reduction lens is also added to the rotation of the image.

When a magnetic correction lens is placed in a lens magnetic field, the sensitivity to the imaging height correction increases, and accordingly, the magnification correction effect also increases. This is because the focusing capability of the lens magnetic field is proportional to square of the on-axis magnetic flux density, thus overlap between the magnetic field of the objective lens and the magnetic field of the magnetic correction lens in the optical axis direction causes a synergetic effect (focusing effect proportional to the product of both magnetic fields) to occur, and a significant change in the focusing capability is obtained for a small change in the correction lens magnetic field. In contrast, when the magnetic correction lens is placed outside the lens magnetic field, change of the focusing capability is extremely small, and correction sensitivity to the imaging height and magnification is extremely reduced.

Therefore, as in this embodiment, the magnetic correction lens 40 placed outside the lens magnetic field has characteristics that the correction sensitivity to the imaging height and magnification is low, and the rotation correction sensitivity is high.

The electrostatic lens placed in the magnetic field of the objective lens (magnetic lens) changes the energy of the beam in the electrostatic lens to change the focusing effect of the beam received from the magnetic lens, thus changes the imaging height. The change of the focusing effect also causes magnification change. Normally, no rotation occurs in the electrostatic lens alone, but when placed in a lens magnetic field, rotation also changes by a magnetic lens effect due to an energy change. Because the magnetic field generated by the objective lens to form an image of the beam is extremely intense, for a small energy change due to a tiny change in the applied voltage of the electrostatic lens, the focusing effect and the rotational effect of the entire lens magnetic field is significantly changed. Therefore, the electrostatic correction lens 67 placed in the lens magnetic field of the final-stage objective lens 17 has a high correction sensitivity to the imaging height, magnification and rotation.

In contrast, the upstream electrostatic correction lens 66 has a low correction sensitivity to the imaging height. This is because the final-stage objective lens 17 reduces the intermediate image IS1 to form an image, thus a beam array image IS2 is formed on the surface of the substrate 24 with reduced change in the height direction. However, the magnification change (ratio of magnification) and rotation remain unchanged. Therefore, the electrostatic correction lens 66 placed inside the lens magnetic field of the upstream objective lens 16 has a low correction sensitivity to the imaging height, but has a high correction sensitivity to the magnification and rotation, substantially comparable to that of the electrostatic correction lens 67.

As described above, the magnetic correction lens 40 and the electrostatic correction lenses 66 and 67 have different correction characteristics (ratio of the imaging height correction sensitivity, the magnification correction sensitivity, and the rotation correction sensitivity is different), thus a mutual relationship between the amounts of excitation (applied voltage in an electrostatic lens, excitation current in a magnetic correction lens) of these three correction lenses is set, and the amounts of excitation are controlled in coordination with each other by an appropriate relational expression, thereby making it possible to correct the imaging state as follows.
* The imaging height is changed corresponding to a variation in the surface height of the substrate with a magnification unchanged and no rotation.
* The magnification is changed with a constant surface height of the substrate, no rotation and an imaging height unchanged.
* The rotation is changed with a constant surface height of the substrate, an imaging height unchanged and a magnification unchanged.

The first correction of the above-mentioned three types of correction to the imaging state is utilized in focus correction (dynamic focus) performed during writing so as to correspond to the irregularities of the sample surface. The second correction can be utilized for fine adjustment of the magnification, and the third correction can be utilized for fine adjustment of rotation.

The relational expression in coordination with the amounts of excitation in correction of the imaging state is different in each of the above-mentioned three patterns of adjustment. When a first or higher degree polynomial of adjustment amounts (imaging height, magnification, rotation) is used as the relational expression between the amounts of excitation, adjustment is possible with sufficient accuracy. The coefficients of the polynomial are determined by a trajectory simulation. The coefficients may be calculated based on the measured dependence of the imaging height, magnification, rotation on the amounts of excitation.

Space for placement can be secured in this embodiment, because it is one electrostatic correction lens that is placed inside the lens magnetic field of the objective lens in each stage as explained above. Since the electrostatic correction lenses are not in proximity, structures, such as a vacuum seal, a wire lead-out from a vacuum area, and an insulator that supports lens electrodes, which are necessary for placing the electrostatic correction lenses can be easily designed. In addition, an assembly work can be made simple, and the work efficiency can be improved.

Since no electrostatic correction lens is placed in proximity inside a lens magnetic field, stay of secondary electrons due to a difference in the voltage across electrostatic lenses in proximity can be prevented, and the beam position can be stabilized.

Note that unlike an electrostatic correction lens, a magnetic correction lens is normally placed outside a vacuum, thus complicated structures, such as a vacuum seal, a wire lead-out from a vacuum area, and an insulator support in a vacuum, are unnecessary.

### Second Embodiment

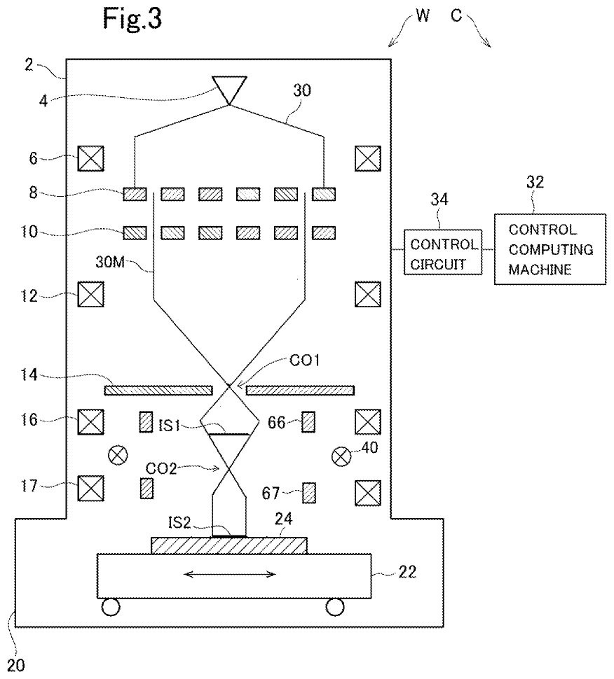

In the first embodiment, a configuration has been described in which the magnetic correction lens 40 is placed between the reduction lens 12 and the objective lens 16, outside a lens magnetic field; however, as illustrated in FIG. 3, the magnetic correction lens 40 may be placed between the two-stage objective lenses 16, 17, outside a lens magnetic field.

For example, when the two objective lenses 16, 17 have opposite excitation directions (directions of the magnetic focusing field), a position occurs where the magnetic flux density is 0 between both lenses, thus the magnetic correction lens 40 is placed near the position.

Even when the two objective lenses 16, 17 have the same excitation direction, a region (for example, a region where the on-axis magnetic flux density is lower than or equal to 1/10 its maximum value) often occurs where the magnetic flux density sufficiently attenuates between both lenses, thus the magnetic correction lens 40 is placed near the region.

### Third Embodiment

In the first embodiment, a configuration has been described in which the electrostatic correction lenses 66, 67 are placed inside respective lens magnetic fields of the objective lenses 16, 17; however, at least one of the electrostatic correction lenses 66, 67 may be replaced by a magnetic correction lens. Note that the electrostatic correction lens and the magnetic correction lens have different structures as well as different implementation forms, thus the “replaced” herein means that lenses are placed at substantially the same position in the optical axis direction. Factors other than position in the optical axis direction, for example, the diameter and length (length in the optical axis direction) of the electrodes of electrostatic correction lens and the coil of magnetic correction lens are normally different.

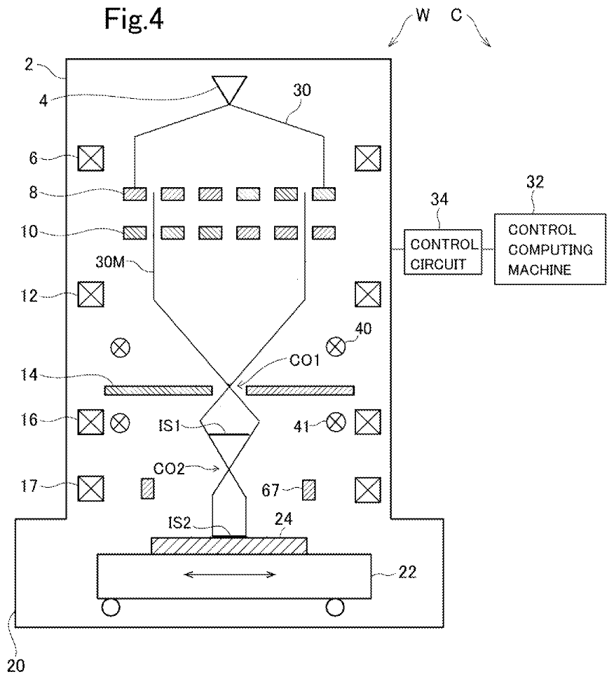

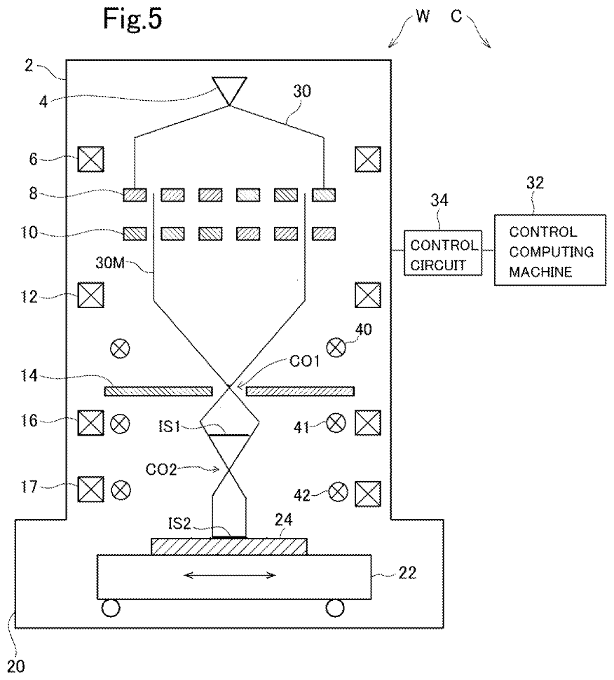

FIG. 4 shows a configuration in which the correction lens in the lens magnetic field of the objective lens 16 is the magnetic correction lens 41, and the correction lens in the lens magnetic field of the objective lens 17 is the electrostatic correction lens 67. FIG. 5 shows a configuration in which the correction lens in the lens magnetic field of the objective lens 16 is the magnetic correction lens 41, and the correction lens in the lens magnetic field of the objective lens 17 is the magnetic correction lens 42.

Although illustration is omitted, the correction lens in the lens magnetic field of the objective lens 16 may be the electrostatic correction lens 66, and the correction lens in the lens magnetic field of the objective lens 17 may be the magnetic correction lens 42.

The magnetic correction lens placed in the magnetic field of the objective lens is an air core circular coil or a solenoid coil. In order to prevent disturbance of the magnetic field of an objective lens, it is preferable not to adopt a structure that is surrounded by a magnetic material such as ferrite.

The magnetic correction lens 42 placed inside the magnetic field of the objective lens 17 has high imaging height correction sensitivity and magnification correction sensitivity. The magnetic correction lens 41 placed inside the magnetic field of the objective lens 16 has a low imaging height correction sensitivity because the imaging height correction amount is reduced by the later-stage objective lens 17, however the magnification correction effect is not affected by the later-stage lens, and high. Therefore, the magnetic correction lens placed inside the lens magnetic field of an objective lens has a ratio of focus to magnification correction sensitivity similar to the ratio when an electrostatic correction lens is placed. In addition, the magnetic correction lens has a high rotation correction sensitivity regardless of inside or outside the magnetic field of the objective lens. Thus, the amounts of excitation of the correction lenses having different correction characteristics, specifically, the excitation currents of the magnetic correction lenses 40, 41 and the applied voltage of the electrostatic correction lens 67 in the embodiment of FIG. 4, and the excitation currents of the magnetic correction lenses 40 to 42 in the embodiment of FIG. 5 are controlled in coordination with each other based on a relational expression, thereby making it possible to appropriately adjust the imaging height, magnification, and rotation of the beam array image IS2.

Unlike an electrostatic correction lens, the magnetic correction lenses (40, 41) placed inside the lens magnetic field of an objective lens are normally placed outside a vacuum, thus a complicated structure is unnecessary, and therefore, space for placement can be secured. Since no electrostatic correction lenses are placed in proximity inside a lens magnetic field, stay of secondary electrons due to a difference in the voltage across electrostatic lenses in proximity can be prevented, and thus the beam position can be stabilized.

### Fourth Embodiment

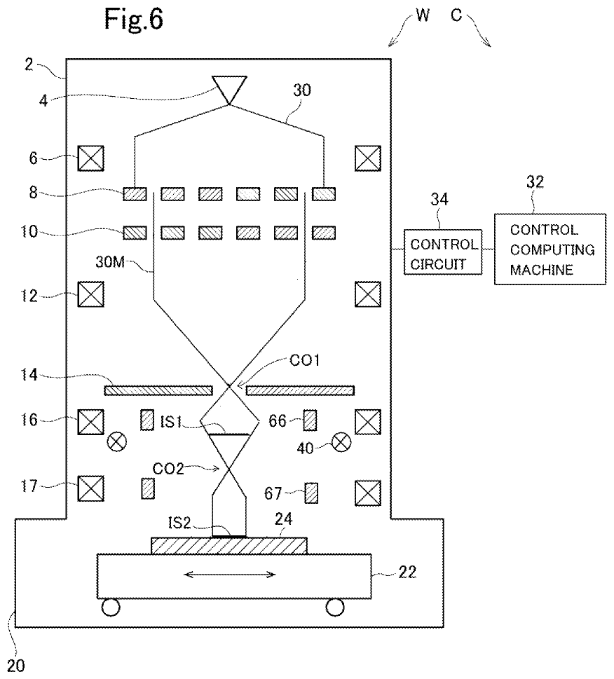

In the second embodiment, a configuration has been described in which the magnetic correction lens 40 is placed between the two-stage objective lenses 16, 17, outside a lens magnetic field; however, the magnetic correction lens 40 may be placed inside the lens magnetic field of the objective lens 16 or the objective lens 17. FIG. 6 illustrates a configuration in which the magnetic correction lens 40 is placed inside the lens magnetic field of the objective lens 16.

The magnetic correction lens 40 is an air core circular coil or a solenoid coil.

Two correction lenses, that is, the electrostatic correction lens 66 and the magnetic correction lens 40 are placed inside the lens magnetic field of the objective lens 16, and both are placed adjacently in the optical axis direction. Since the magnetic correction lens 40 can be placed outside a vacuum, space for placing electrostatic correction lenses can be secured. Although the two correction lenses are adjacent in the optical axis direction, the magnetic correction lens does not change the electrical potential near the optical axis, thus stay of secondary electrons due to a difference in the voltage across lenses in proximity does not occur, and the beam position can be stabilized.

The magnetic correction lens 40 placed inside the lens magnetic field of the objective lens 16 has a low correction sensitivity to the imaging height, and has a high correction sensitivity to the magnification and rotation.

Even when the magnetic correction lens 40 is placed at a position away from the center of a lens magnetic field, where the magnetic field is weak, the sensitivity to rotation correction remains unchanged. Thus, placement of the magnetic correction lens 40 away from the electrostatic correction lens 66 in the optical axis direction allows further space for placing the electrostatic correction lens 66 to be ensured.

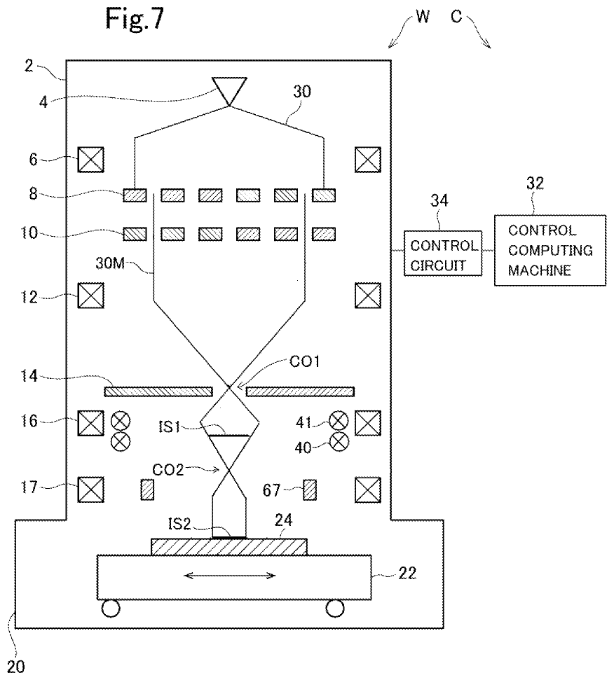

As illustrated in FIG. 7, the electrostatic correction lens 66 in the lens magnetic field of the objective lens 16 may be replaced by the magnetic correction lens 41.

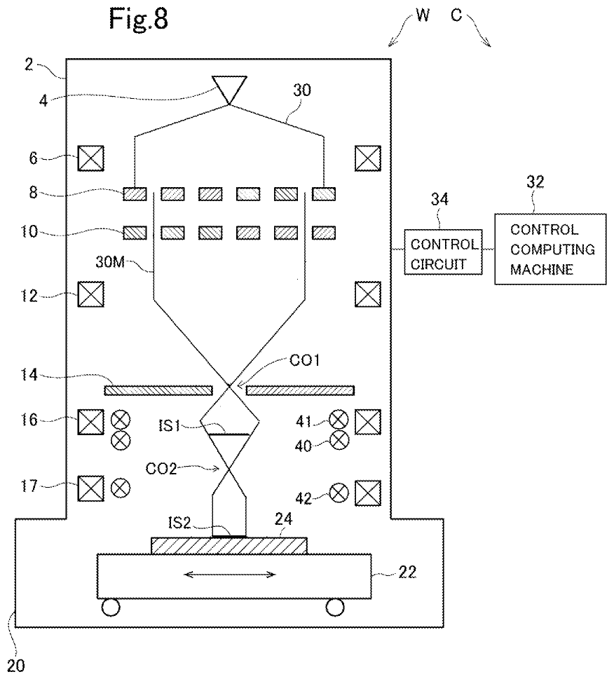

As illustrated in FIG. 8, the electrostatic correction lens 66 in the lens magnetic field of the objective lens 16 may be replaced by the magnetic correction lens 41, and the electrostatic correction lens 67 in the lens magnetic field of the objective lens 17 may be replaced by the magnetic correction lens 42.

Use of a magnetic correction lens allows the correction lens to be placed outside a vacuum, thus space for placing the correction lens can be ensured. Although the two correction lenses (the magnetic correction lenses 40, 41) are adjacent in the optical axis direction, the magnetic correction lens does not change the electrical potential near the optical axis, thus stay of secondary electrons due to a difference in the voltage across lenses in proximity does not occur, and the beam position can be stabilized.

Unlike an electrostatic correction lens, even when a magnetic correction lens is placed at a position away from the center of an objective lens magnetic field, where the magnetic field is weak, the sensitivity to rotation correction remains unchanged. Thus, placement of magnetic correction lenses away in the optical axis direction allows further space for placement to be ensured.

When the correction sensitivity of each of the correction lenses in the objective lens magnetic field is studied in detail, the correction sensitivity other than the rotation correction sensitivity of the magnetic correction lens depends on the objective lens magnetic field intensity (magnetic flux density) at the correction lens position, and the beam trajectory value (the distance from the optical axis) at the correction lens position. In addition, the dependence differs according to which correction sensitivity (one of the imaging height correction sensitivity, the magnification correction sensitivity, and the rotation correction sensitivity). Therefore, even in the lens magnetic field of the same objective lens, if the positions of two correction lenses are shifted and placed in the beam optical axis direction, the magnetic field intensities and trajectory values at the positions are different, thus different correction sensitivities are obtained. As a result, also in the example illustrated in FIG. 6 to FIG. 8, the correction lenses have different correction characteristics, thus correction to the imaging state, specifically, correction to the imaging height, magnification, rotation of the beam array image IS2 can be appropriately made by controlling the amounts of excitation of these three correction lenses in coordination with each other by an appropriate relational expression.

Note that an electrostatic correction lens and a magnetic correction lens are not simply replaceable to each other. When an electrostatic correction lens is placed inside the magnetic field of an objective lens (magnetic lens), the electrostatic correction lens functions without a problem; however, when an electrostatic correction lens is placed outside a magnetic field, the sensitivity becomes extremely low, and it is difficult to make imaging height correction, magnification correction, as well as rotation correction. In contrast, a magnetic correction lens has a high sensitivity to rotation correction even when being placed outside a magnetic field. Therefore, replacement between both lenses is not simple, and there are a case where both lenses can be replaced, and a case where both lenses cannot be replaced. For example, the magnetic correction lens 40 in the embodiment of FIG. 1 and FIG. 3 cannot be replaced by an electrostatic correction lens.

In the writing apparatus presented so far, a configuration using three correction lenses has been described, but the number of correction lenses used for correction of the imaging state is not limited to three, and may be four or more.

In the writing apparatus presented so far, a configuration using two-stage objective lenses has been described; however, even when three or more-stage objective lenses are used, the imaging state can be corrected while securing a space for placing a focus correction lens and producing the effect of preventing stay of secondary electrons and stabilizing the beam irradiation position.

Although the present invention has been described in detail with reference to particular embodiments, it will be apparent to those skilled in the art that various modifications may be made therein without departing from the spirit and scope of the present invention.

### REFERENCE SIGNS LIST

2 ELECTRON OPTICAL COLUMN
4 ELECTRON SOURCE
6 ILLUMINATION LENS
8 SHAPING APERTURE ARRAY SUBSTRATE
10 BLANKING APERTURE ARRAY SUBSTRATE
14 LIMITING APERTURE MEMBER
16, 17 OBJECTIVE LENS
20 WRITING CHAMBER
22 XY STAGE
24 SUBSTRATE
40, 41, 42 MAGNETIC CORRECTION LENS
66, 67 ELECTROSTATIC CORRECTION LENS

1. A multi charged particle beam writing apparatus comprising:
a plurality of blankers performing blanking deflection on each of beams in a multi charged particle beam;
a limiting aperture member blocking a beam in the multi charged particle beam, the beam being deflected by the blanker to achieve a beam-OFF state;
two or more-stage objective lenses each comprised of a magnetic lens, and configured to focus the multi charged particle beam on a substrate, which has passed through the limiting aperture member; and
three or more correction lenses correcting an imaging state of the multi charged particle beam on the substrate,
wherein the three or more correction lenses are comprised of a first magnetic correction lens, and two or more correction lenses,
the two or more correction lenses are placed inside a lens magnetic field of one of the two or more-stage objective lenses, and
one or no electrostatic correction lens is placed inside a magnetic field of each of the two or more-stage objective lenses.

2. The multi charged particle beam writing apparatus according to claim 1,
wherein the first magnetic correction lens is placed outside the magnetic field of the two or more-stage objective lenses.

3. The multi charged particle beam writing apparatus according to claim 2,
wherein the two or more correction lenses include two electrostatic correction lenses, and
the two electrostatic correction lenses are placed inside lens magnetic fields of different objective lenses of the two or more-stage objective lenses.

4. The multi charged particle beam writing apparatus according to claim 2,
wherein the two or more correction lenses include a first electrostatic correction lens and a second magnetic correction lens, and
the first electrostatic correction lens and the second magnetic correction lens are placed inside lens magnetic fields of different objective lenses of the two or more-stage objective lenses.

5. The multi charged particle beam writing apparatus according to claim 2,
wherein the two or more correction lenses include two magnetic correction lenses, and
the two magnetic correction lenses are placed inside lens magnetic fields of different objective lenses of the two or more-stage objective lenses.

6. The multi charged particle beam writing apparatus according to claim 1,
wherein the first magnetic correction lens is placed inside a magnetic field of one of the two or more-stage objective lenses.

7. The multi charged particle beam writing apparatus according to claim 6,
wherein the two or more correction lenses include two electrostatic correction lenses, and
the two electrostatic correction lenses are placed inside lens magnetic fields of different objective lenses of the two or more-stage objective lenses.

8. The multi charged particle beam writing apparatus according to claim 6,
wherein the two or more correction lenses include a first electrostatic correction lens and a second magnetic correction lens, and
the first electrostatic correction lens and the second magnetic correction lens are placed inside lens magnetic fields of different objective lenses of the two or more-stage objective lenses.

9. The multi charged particle beam writing apparatus according to claim 6,
wherein the two or more correction lenses include two magnetic correction lenses, and
the two magnetic correction lenses are placed inside lens magnetic fields of different objective lenses of the two or more-stage objective lenses.

10. The multi charged particle beam writing apparatus according to claim 1,
wherein a mutual relationship between amounts of excitation of the three or more correction lenses is set, and the imaging state of the multi charged particle beam is corrected.

11. The multi charged particle beam writing apparatus according to claim 10,
wherein the correction of the imaging state is such that an imaging height is changed with a magnification unchanged and no rotation.

12. The multi charged particle beam writing apparatus according to claim 10,
wherein the correction of the imaging state is such that magnification is changed with no rotation and an imaging height unchanged.

13. The multi charged particle beam writing apparatus according to claim 10,
wherein the correction of the imaging state is such that rotation is changed with an imaging height unchanged and a magnification unchanged.
